(19) United States
(12) Patent Application Publication
(10) Pub. No.: US 2025/0323776 A1
(43) Pub. Date: Oct. 16, 2025

(54) SYSTEM AND METHOD FOR HYBRID PHASE DETECTION AND CLOCK RECOVERY

(71) Applicant: MaxLinear, Inc., Carlsbad, CA (US)

(72) Inventors: Rishi Mathur, Bengaluru (IN); Pradeep Kola, Bengaluru (IN); Bibek Jyoti Das, Bengaluru (IN); Deep Bharat Mistry, Bengaluru (IN)

(73) Assignee: MaxLinear, Inc., Carlsbad, CA (US)

(21) Appl. No.: 19/176,060

(22) Filed: Apr. 10, 2025

(30) Foreign Application Priority Data
Apr. 10, 2024 (IN) 202411029255

(51) Int. Cl. H04L 7/00

(52) U.S. Cl. CPC H04L 7/0062; H04L 7/0016

(57) ABSTRACT

System and methods are disclosed for hybrid phase detection and clock recovery in a serializer/deserializer (SerDes) receiver. The system enables a clock recovery unit (CRU) to dynamically operate in either a Mueller-Muller Phase Detection (MMPD) mode or an Alexander Phase Detection (APD) mode using shared circuit components. The CRU includes data and error slicers configured to generate phase error signals based on a received data stream, with the phase detector adapting the recovered clock signal accordingly. The system utilizes adjustable reference voltage levels and signal gating logic to repurpose MMPD hardware to emulate APD functionality without impacting high-speed data paths. Such architecture supports various interleaving configurations, including even-odd and n-way time-interleaved designs, and enables on-the-fly mode switching based on channel conditions or baud rate requirements.

### RELATED APPLICATION

This application claims the benefit of India Provisional Patent Application No. 202411029255 filed Apr. 10, 2024, the disclosure of which is incorporated herein by reference in its entirety.

### BACKGROUND

Serializer/deserializer (SerDes) integrated circuit systems for converting data between serial and parallel interfaces in communications and computing are known. Phase detection in SerDes clock recovery by comparing the phase of the incoming data signal with a locally generated clock signal to adjust the timing of the local clock is also known. Yet some SerDes systems, when used for high-speed communication between integrated circuits, lack effective phase detection and clock recovery. As a result, maintaining data integrity and synchronization across the transmission channel is cumbersome.

Some SerDes systems face challenges related to power consumption and efficiency. For example, high-speed transceivers that require more power due to complex signal processing needed for maintaining signal integrity. With the increased data transmission rates, maintaining signal integrity becomes even more sophisticated and requires power-intensive signal processing to ensure data accuracy, further elevating the power requirements. The complexity and cost of such SerDes systems rise with the need for advanced circuitry. The design complexity, increased silicon area, and the costs associated with implementing the necessary components for clock recovery and equalization all contribute to high power consumption.

### SUMMARY

Some embodiments include a system for a serializer/deserializer (SerDes) receiver operable to selectively implement Mueller-Muller Phase Detection (MMPD) and Alexander Phase Detection (APD) for clock recovery. In some embodiments, the system includes a data slicer, an error slicer, a phase detector configured to operate in a first mode corresponding to MMPD and a second mode corresponding to APD. In some embodiments, the phase detector adjusts the phase of a recovered clock signal based on error signals generated by the data slicer or the error slicer.

Some embodiments include a method for dual-mode phase detection in a serializer/deserializer (SerDes) system. The method includes operating a clock recovery unit (CRU) in a first mode utilizing Mueller-Muller Phase Detection (MMPD) based on a first set of reference voltages and switching to a second mode utilizing Alexander Phase Detection (APD) by modifying the reference voltages. In some embodiments include a method for operating a clock recovery system in a SerDes receiver. The method includes selecting between an MMPD mode and an APD mode based on operational requirements. In some embodiments, the method includes altering reference voltage levels of error slicers to correspond with the selected mode and processing error signals to adjust a recovered clock signal in accordance with the selected mode.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is noted, however, that the appended drawings illustrate only some aspects of this disclosure and the disclosure may admit to other equally effective embodiments.

To facilitate understanding, identical reference numerals have been used, where possible, to designate identical elements that are common to the figures. It is contemplated that elements and features of one embodiment may be beneficially incorporated in other embodiments without further recitation.

FIG. 1 illustrates a schematic of an exemplary receiver system, in accordance with some embodiments;

FIG. 2A illustrates a schematic of an exemplary receiver system, in accordance with some embodiments;

FIG. 2B illustrates a graph of an exemplary receiver system signal, in accordance with some embodiments;

FIGS. 3A-3B illustrates graphs of exemplary receiver system signals, in accordance with some embodiments;

FIG. 4 illustrates a schematic of an exemplary receiver system, in accordance with some embodiments;

FIGS. 5A-5B illustrate schematics of exemplary receiver systems, in accordance with some embodiments;

FIGS. 6-7 depicts flowcharts corresponding to methods corresponding to an exemplary receiver system; in accordance with some embodiments.

### DETAILED DESCRIPTION

The present disclosure will now be described in detail with reference to the drawings, which are provided as illustrative examples of the disclosure so as to enable those skilled in the art to practice the disclosure. Notably, the figures and examples below are not meant to limit the scope of the present disclosure to a single embodiment, but other embodiments are possible by way of interchange of some or all of the described or illustrated elements. Moreover, where certain elements of the present disclosure can be partially or fully implemented using known components, only those portions of such known components that are necessary for an understanding of the present disclosure will be described, and detailed descriptions of other portions of such known components will be omitted so as not to obscure the disclosure.

As used herein, the singular form of “a”, “an”, and “the” include plural references unless the context clearly dictates otherwise. As used herein, the statement that two or more parts or components are “coupled” shall mean that the parts are joined or operate together either directly or indirectly (i.e., through one or more intermediate parts or components, so long as a link occurs). As used herein, “directly coupled” means that two elements are directly in contact with each other. As used herein, “fixedly coupled” or “fixed” means that two components are coupled so as to move as one while maintaining a constant orientation relative to each other. As used herein, “operatively coupled” means that two elements are coupled in such a way that the two elements function together. It is to be understood that two elements “operatively coupled” does not require a direct connection or a permanent connection between them. As utilized herein, “substantially” means that any difference is negligible, or that such differences are within an operating tolerance that are known to persons of ordinary skill in the art and provide for the desired performance and outcomes as described in one or more embodiments herein. Descriptions of numerical ranges are endpoints inclusive.

As used herein, the word “unitary” means a component is created as a single piece or unit. That is, a component that includes pieces that are created separately and then coupled together as a unit is not a “unitary” component or body. As employed herein, the statement that two or more parts or components “engage” one another shall mean that the parts exert a force against one another either directly or through one or more intermediate parts or components. As employed herein, the term “number” shall mean one or an integer greater than one (i.e., a plurality). Directional phrases used herein, such as, for example and without limitation, top, bottom, left, right, upper, lower, front, back, and derivatives thereof, relate to the orientation of the elements shown in the drawings and are not limiting upon the claims unless expressly recited therein.

Embodiments described as being implemented in hardware should not be limited thereto, but can include embodiments implemented in software, or combinations of software and hardware, and vice-versa, as will be apparent to those skilled in the art, unless otherwise specified herein. In the exemplary embodiments described herein, an embodiment showing a singular component should not be considered limiting; rather, the invention is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present invention encompasses present and future known equivalents to the known components referred to herein by way of illustration.

The embodiments described herein relate generally to a phase interpolator (PI) based SerDes receiver (hereinafter “the receiver”) that significantly enhances power consumption efficiency and management with an adaptable clock recovery implementation. In some embodiments, a clock recovery unit (CRU) is capable of implementing both so-called “Alexander Phase Detection” (APD) and so-called “Mueller-Muller Phase Detection” (MMPD) within the same unit, which is described below.

MMPD is advantageous in high data rate SerDes applications due to power efficiency. However, MMPD's robustness is compromised at lower channel losses, where APD is superior due to robust locking mechanism, which remains effective regardless of channel loss magnitude. The embodiments described herein harnesses the robustness of APD and the power efficiency of MMPD without the need for separate phase detection mechanisms. For example, some approaches using MMPD across a broad frequency spectrum are challenged when the same link is operating at varying data rates and channel conditions. High-speed operations with significant channel loss contrast with lower-speed operations where channel loss is minimal.

The dependence of MMPD's locking point on pulse response complicates the application across different channel losses. Such variability strains the Continuous Time Linear Equalizer (CTLE), which precedes the phase detector, requiring the equalizer to accommodate a wide dynamic range of gain adjustments and frequency peaking. Thus, the embodiments described below facilitate a SerDes CRU to seamlessly switch between APD and MMPD. Such adaptability ensures robust and efficient phase detection across diverse operating conditions and data rates. As described in detail below, by reconfiguring existing circuit elements within the CRU, the embodiments described herein obviates the need for separate mechanisms and/or circuitry for APD and MMPD, thereby simplifying manufacturing and reducing the power consumption of the CRU. This not only enhances the performance of the receiver and SerDes systems of the embodiments herein but also alleviates the stringent requirements placed on the CTLE architecture, thereby facilitating a more efficient and versatile communication system.

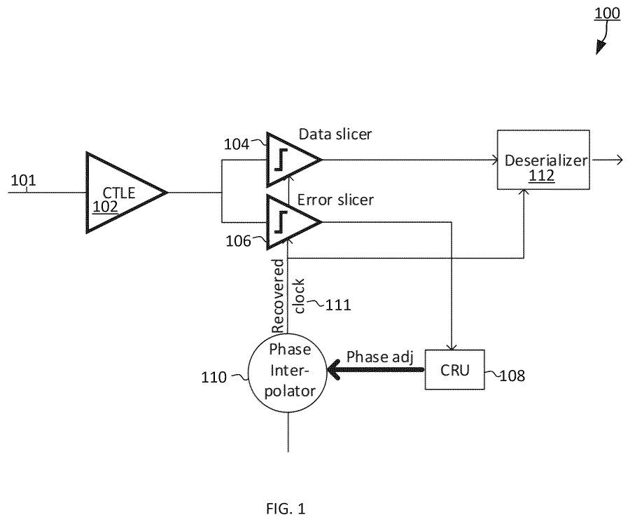

Referring now to FIG. 1A, FIG. 1 illustrates an exemplary PI based SerDes Receiver System 100 (hereinafter “system 100”). In some embodiments, system 100 includes CTLE 102, data slicer 104, error slicer 106, CRU 108, PI 110, and deserializer 112.

As shown in FIG. 1, some embodiments, include system 100 having a phase interpolator (PI) based SerDes receiver. In some embodiments, CTLE 102 may be an input to compensate for channel loss, followed by Data slicer 104 and error slicer 106. Data/Error slicers 104, 106 generate error signals for Clock Recovery Unit (CRU) 108 adaptation. For example, while data slicers generate received data. Slicers 104, 106 are driven by the recovered clock. In some embodiments, system 100 may include additional Decision Feedback Equalization (DFE), Feed forward Equalization (FFE), or a reference clock less CRU (Not shown for simplicity).

As shown in FIG. 1, system 100 advantageously employs a phase interpolator (PI)-based architecture that ensures the high fidelity of data transmission over serial communication channels. In some e, system 100 may compensate for channel loss and to recover the timing of incoming signals for accurate data deserialization. In some e, Continuous Time Linear Equalizer (CTLE) 102 serves to mitigate the effects of channel loss, which is attributed to factors such as the resistive and capacitive properties of the transmission medium. In some e, CTLE 102 dynamically adjusts input signal 101, amplifying the high-frequency components that tend to be attenuated during transmission, thus preparing input signal 101 for further processing. CTLE 102 is in communication with data slicer 104 and error slicer 106. Such components (102, 104, 106) are advantageous for translating the analog waveforms of the received signal (e.g., 101) into digital data. In some embodiments, data slicer 104 operates on the principle of decision-making at each clock interval, determining whether the bit value should be a ‘l’ or a ‘O’ based on the reference voltage at the moment the recovered clock indicates the trigger time to sample the signal.

In some embodiments, concurrently, or substantially concurrently, error slicer 106 may detect discrepancies in the timing of signal 101's transitions. Error slicer 106 may compare incoming signal 101's phase with the phase of recovered clock 111 and produces an error signal when there is a misalignment. Such error signal may be indicative of the phase difference and is advantageous for the adaptation of the Clock Recovery Unit (CRU) 108, which is discussed in detail below.

In some embodiments, CRU 108 may be driven by the error signals from the slicers 104, 106, and may adjust the phase of the local clock (not shown) to align the clock signals more closely with the incoming data signal 101's transitions. Such synchronization or alignment of the clock signals may be facilitated by phase interpolator (PI) 110. For example, PI 110 may finely adjust the clock's phase in response to CRU 108's control signals. By interpolating between phases, PI 110 provides a smooth and precise control mechanism for CRU 108 to lock onto the correct phase of the incoming data stream (i.e., input signal 101).

In some embodiments, system 100 may include additional equalization techniques, such as Decision Feedback Equalization (DFE) and/or Feed Forward Equalization (FFE) (not shown in FIG. 1). For example, DFE is advantageous for correcting errors based on previously detected bits, while FFE may advantageously preemptively condition input signal 101 to counteract anticipated dispersion effects.

In some embodiments, system 100 may include a reference clock-less CRU implementation, which would eliminate the need for a standalone reference clock by deriving timing information directly from the data stream itself. Such implementation may simplify the receiver design and reduce dependency on external timing sources, and is discussed in further detail below. Thus system 100 is highly adaptive and capable of compensating for various impairments introduced by the communication channel. By employing the embodiments described herein, system 100 ensures that the serial data is accurately converted back to parallel form, maintaining the integrity and efficiency of high-speed data communications.

In the embodiments herein, system 100 components (e.g., 102, 104, 106, 108, 110, and/or 112) may include a number of processing units and/or CPUs. Use in any application involving processors and/or software: One or more aspects or features of the subject matter described herein can be realized in digital electronic circuitry, integrated circuitry, specially designed application specific integrated circuits (ASICs), field programmable gate arrays (FPGAs) computer hardware, firmware, software, and/or combinations thereof. These various aspects or features can include implementation in one or more computer programs that are executable and/or interpretable on a programmable system including at least one programmable processor, which can be special or general purpose, coupled to receive data and instructions from, and to transmit data and instructions to, a storage system, at least one input device, and at least one output device. The programmable system or computing system may include clients and servers. A client and server are generally remote from each other and typically interact through a communication network. The relationship of client and server arises by virtue of computer programs running on the respective computers and having a client-server relationship to each other.

These computer programs, which can also be referred to programs, software, software applications, applications, components, or code, include machine instructions for a programmable processor, and can be implemented in a high-level procedural language, an object-oriented programming language, a functional programming language, a logical programming language, and/or in assembly/machine language. As used herein, the term “machine-readable medium” (or “computer readable medium”) refers to any computer program product, apparatus and/or device, such as for example magnetic discs, optical disks, memory, and Programmable Logic Devices (PLDs), used to provide machine instructions and/or data to a programmable processor, including a machine-readable medium that receives machine instructions as a machine-readable signal. The term “machine-readable signal” (or “computer readable signal”) refers to any signal used to provide non-transitory machine readable instructions and/or data to a programmable processor. The machine-readable medium can store such machine instructions non-transitorily, such as for example as would a non-transient solid-state memory or a magnetic hard drive or any equivalent storage medium. The machine-readable medium can alternatively or additionally store such machine instructions in a transient manner, such as for example as would a processor cache or other random access memory associated with one or more physical processor cores.

To provide for interaction with a user, one or more aspects or features of the subject matter described herein can be implemented on a computer having a display device, such as for example a cathode ray tube (CRT) or a liquid crystal display (LCD) or a light emitting diode (LED) monitor for displaying information to the user and a keyboard and a pointing device, such as for example a mouse or a trackball, by which the user may provide input to the computer. Other kinds of devices can be used to provide for interaction with a user as well. For example, feedback provided to the user can be any form of sensory feedback, such as for example visual feedback, auditory feedback, or tactile feedback; and input from the user may be received in any form, including, but not limited to, acoustic, speech, or tactile input. Other possible input devices include, but are not limited to, touch screens or other touch-sensitive devices such as single or multi-point resistive or capacitive trackpads, voice recognition hardware and software, optical scanners, optical pointers, digital image capture devices and associated interpretation software, and the like.

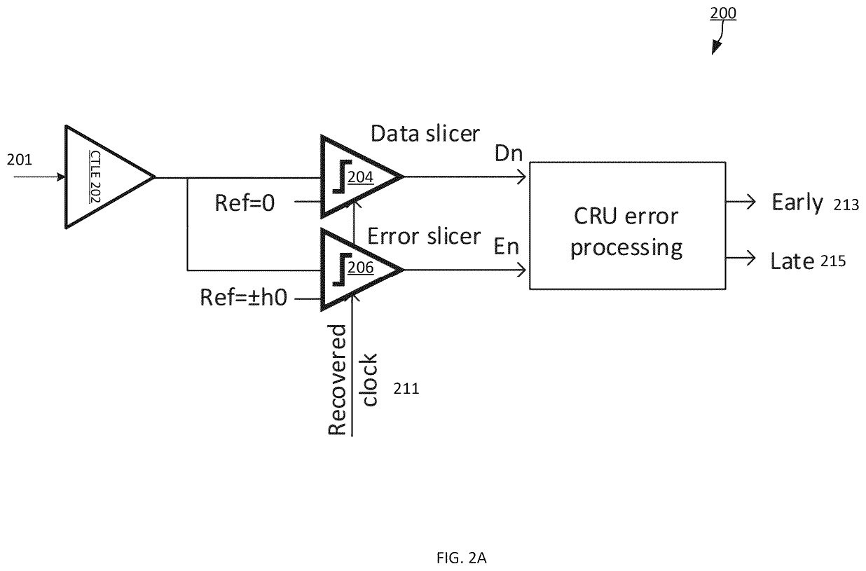

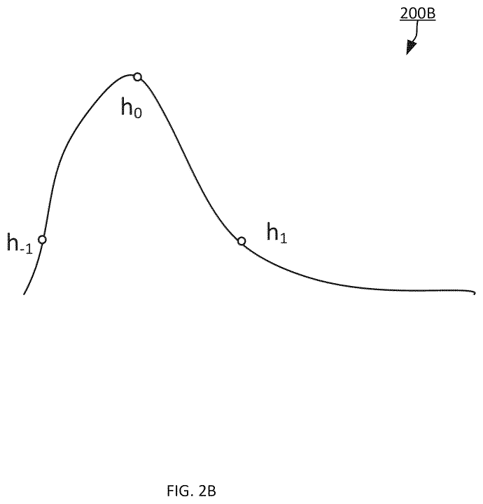

Referring now to FIGS. 2A-2B, FIG. 2A depicts an exemplary PI based SerDes Receivers System 200 (hereinafter “system 200”). FIG. 2A depicts system 200A configured for data and error generation. System 200A is an embodiment of system 100, wherein similarly labeled parts and numbers correspond to similar features having similar functionality. In some embodiments, system 200A includes CTLE 202, data slicer 204, error slicer 206, CRU 208, PI 210, and deserializer 212. FIG. 2B illustrates a pulse response for a high loss channel cascaded with CTLE in accordance with some embodiments, which is discussed in further detail below.

As shown in FIG. 2B, in some embodiments, system 200B implements a method that makes the lock point as h₋₁−h₁=0, herein construed as the so-called “MMPD requirement”. For example, in some embodiments, receiver input Xₙ and error slicer output Eₙ may be denoted by the following equation:

$${X}_{n} = {D}_{n + 1} . {h}_{- 1} + {D}_{n} . {h}_{0} + {D}_{n - 1} . {h}_{1} ; and \qquad ( Eqn . 1 a )$$

$${E}_{n} = {X}_{n} - {h}_{0} \qquad ( Eqn . 1 b )$$

In some embodiments, reference numeral 201 denotes the input signal to CTLE 202. Input signal 201 may represent a high-speed serial data stream received over a communication channel. This signal may be subject to frequency-dependent loss and distortion, and thus is equalized by CTLE 202 before being sampled by slicers 204 and 206.

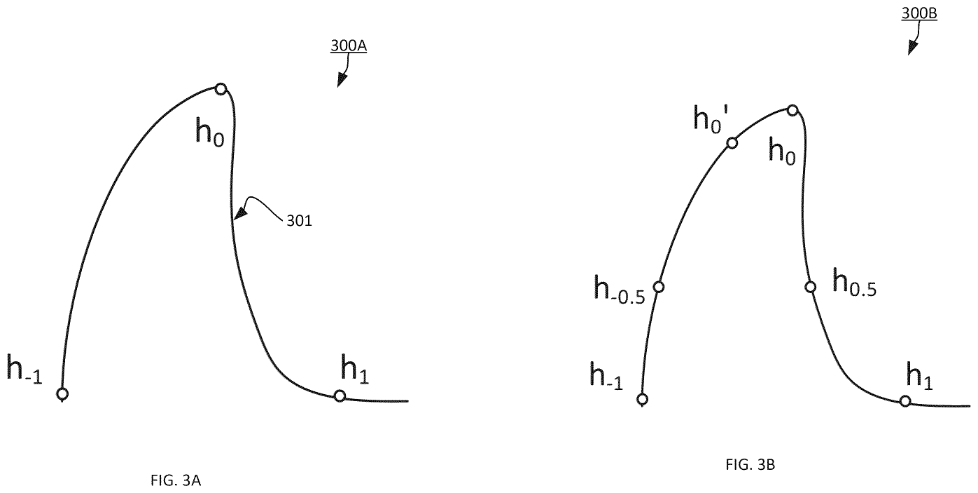

In FIG. 2B, 200B denotes an illustrative representation of the receiver system described in FIG. 2A, showing its behavior under a specific channel response scenario. Similarly, in FIG. 3B, 300B denotes a graphical waveform plot illustrating pulse response and optimal lock point alignment (h−0.5=h₀.5) for Alexander Phase Detection. The waveform shows the impact of oversampling, emphasizing the value of 2×UI spacing for phase detection accuracy in low-loss environments.

In some instances when Xₙ is not available in digital data to implement correlation and CTLE is not followed by an ADC (i.e., slicers are in digital domain). Accordingly, in such instances an approximation may be implemented based on:

$${D}_{n - 1} . {E}_{n} - {D}_{n} . {E}_{n - 1} = {D}_{n - 1} . ( {D}_{n + 1} . {h}_{- 1} + {D}_{n} . {h}_{0} + {D}_{n - 1} . {h}_{1} - {h}_{0} ) - {D}_{n} . ( {D}_{n} . {h}_{- 1} + {D}_{n - 1} . {h}_{0} + {D}_{n - 2} . {h}_{1} - {h}_{0} ) = h {1}_{-} {h}_{- 1} \qquad ( Eqn . 2 )$$

In some embodiments, such implementation may be executed by CRU error processing unit 209, using the truth table shown in Table 1. For example, early and late signals 213, 215 from CRU error processing 209 may be counted using up/down counters (not shown) and then processed in the CRU loop. Such processing in the CRU loop may be implemented using digital circuit for controlling the phase/frequency of the recovered clock 211.

TABLE 1
Truth table for MMPD

| Dn − 1 | Dn | Dn + 1 | xn − h0 | xn + h0 | Early/late |
|---|---|---|---|---|---|
| 0 | 1 | 1 | 0 | 1 | Early |
| | | | 1 | | Late |
| 0 | 0 | 1 | 0 | 0 | Early |
| | | | | 1 | Late |
| 1 | 1 | 0 | 0 | 1 | Late |
| | | | 1 | | Early |
| 1 | 0 | 0 | 0 | 0 | Late |
| | | | | 1 | Early |

Referring now to FIGS. 3A-3B, in conjunction with FIGS. 1-2, FIG. 3A depicts graph 300A showing pulse response for a low loss channel cascaded with CTLE with some loss. As shown in FIG. 3A, the receiver of the embodiments herein operates to ensure h₋₁=h₁ makes a lock point such that h₀ might be sampled close to peak voltage yet at or substantially at the falling edge 301. With such lock point, CRU may not have an optimal jitter margin. In such cases a better lock point is h_{-0.5}=h_{0.5}, which is shown in FIG. 3B. This feature is analogous to MMPD apart from the fact 2 samples per baud are needed. In some embodiments, 2 samples per baud may be realized with substantially similar equations, h_{-0.5}=h_{0.5}. Such equations may include:

$${E}_{n - 0.5} {D}_{n} - {E}_{n - 0.5} {D}_{n - 1} = 0 \qquad ( Eqn . 3 )$$

[Eqn. 3 is the APD equation, and may be seen as correlation of E_{n-0.5} is equal to Dₙ and Dₙ₋₁]

Substituting (Eqn. 3) for 2× mode, (i.e., 1 UI becomes 0.5 UI):

$${D}_{n - 0.5} . {E}_{n} - {D}_{n} . {E}_{n - 0.5} \qquad ( Eqn . 4 )$$

Substituting Eqn. 4 for two consecutive samples:

$${D}_{n - 1} . {E}_{n - 0.5} - {D}_{n - 0.5} . {E}_{n - 1 ;} and \qquad ( Eqn . 5 a )$$

$${D}_{n - 0.5} . {E}_{n} - {D}_{n} . {E}_{n - 0.5} \qquad ( Eqn . 5 b )$$

Thus, By forcing Eₙ=0 for n being integer, and comparing sum of Eqn. 5a and 5b zeros, the result becomes the APD equation:

$${D}_{n - 1} . {E}_{n - 0.5} - {D}_{n} . {E}_{n - 0.5} = 0 \qquad ( Eqn . 6 )$$

Accordingly Eqns. 1-6 above illustrate that to implement APD in a MMPD circuit, some embodiments herein may force Eₙ=1 for n being integer (and ignore data Dₙ for n not being integer) when system 100 is in 2× oversampling mode. In some embodiments, implementing the 2× oversampling mode becomes even simpler in presence of even odd time interleaved architecture, which is discussed in detail below.

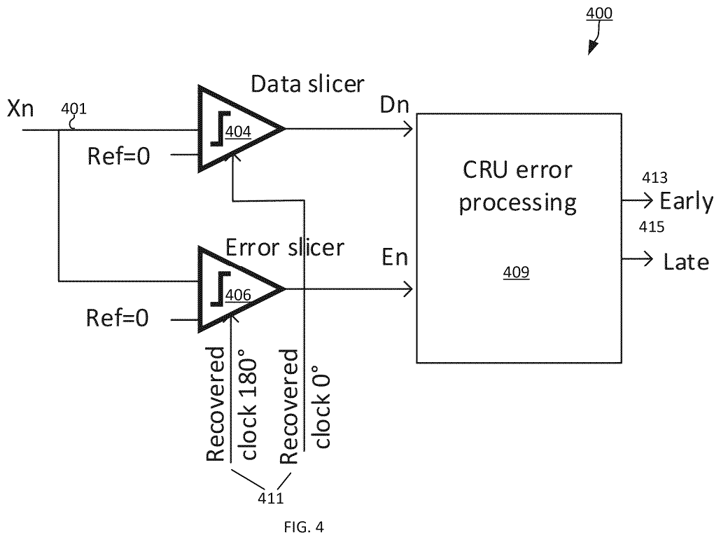

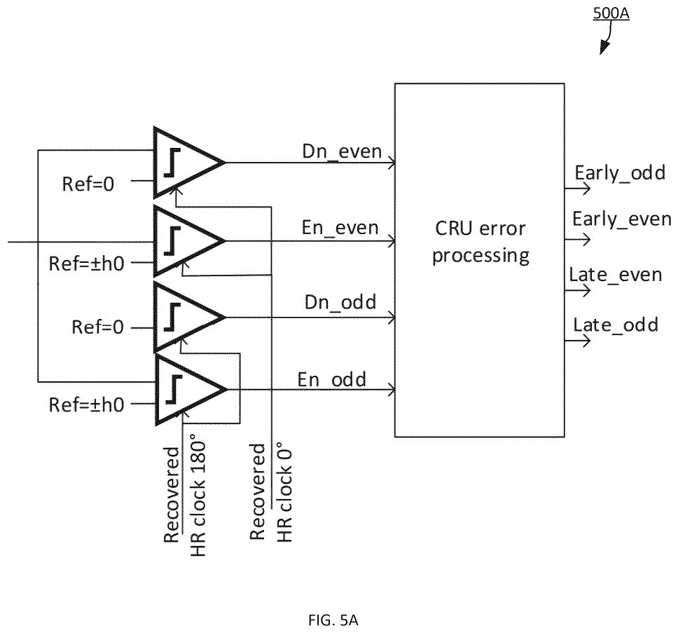

Referring now to FIG. 4 in conjunction with FIGS. 1-3, FIG. 4 depicts an APD CRU system 400 (system 400). System 400 is an embodiment of system 200, wherein similarly labeled parts and numbers correspond to similar features having similar functionality. In some embodiments, system 400 may operate to execute a method or implementation that may be executed based on the truth table for MMPD shown in Table 2 in the CRU error processing unit.

TABLE 2
Truth table for MMPD

| Dn − 1 | En − 0.5 | Dn | Early/late |
|---|---|---|---|
| 0 | 1 | 1 | Late |
| 0 | 0 | 1 | Early |
| 1 | 1 | 0 | Early |
| 1 | 0 | 0 | Late |

Table 2 encapsulates the truth table for Mueller-Muller Phase Detection (MMPD) logic, which is advantageous to the functionality of a Clock Recovery Unit (CRU) within a SerDes system 200. Table 2 indicates how system 400 may respond to various combinations of the current bit (Dn), the previous bit (Dn−1), and the error signal (En−0.5) that has been sampled halfway between the current and the previous bit period.

In some embodiments, table 2 may be organized as follows. The first column, Dn−1, represents the data bit prior to the current bit being considered. The second column, En−0.5, indicates the error signal value sampled at a halfway point between Dn−1 and Dn. It represents the phase error detected by the error slicer at that specific point in time. The third column, Dn, is the current data bit being sampled. The fourth column specifies the output of the phase detector, indicating whether the system should adjust the clock phase earlier or later.

Referring to FIG. 4, 401 denotes the overall APD-enabled receiver system, which is an embodiment of the system shown in FIG. 2A. Block 404 corresponds to a data slicer, and block 406 corresponds to an error slicer, both of which are configured to operate using zero reference voltages when the system is in APD mode. Block 411 represents the recovered clock signal generated by the clock recovery loop and used to drive the sampling of slicers 404 and 406. This recovered clock is dynamically adjusted based on phase error signals. Ouptut 413 indicates the early signal output from the error slicer, while output 415 denotes the late signal output. These signals are evaluated by the CRU error processing logic to determine necessary clock phase adjustments. In APD mode, either output 413 or 415 may be selectively ignored, depending on the architecture, to simulate two-sample-per-baud behavior as described in APD processing logic.

In some embodiments, the logic described by Table 2 functions to guide the phase adjustment mechanism within the CRU as follows, when Dn−1 is 0, En−0.5 is 1, and Dn is 1, the signal is considered ‘Late’. This means that the data transitions are happening after the expected time, suggesting that the recovered clock is leading the data signal. To correct such leading, the CRU would delay the clock.

In some embodiments, when Dn−1 is 0, En−0.5 is 0, and Dn is 1, the signal is ‘Early’. In such case, the data transitions are occurring before the expected time, which means the recovered clock is lagging behind the data signal. CRU 409 may advance the clock to correct this discrepancy. When Dn−1 is 1, En−0.5 is 1, and Dn is 0, the signal is again ‘Early’, indicating the same adjustment as in the second scenario. In some embodiments, when Dn−1 is 1, En−0.5 is 0, and Dn is 0, the signal is ‘Late’, requiring the same adjustment as in the first scenario.

In the context of dual-functionality with APD, system 400 may be modified such that when APD mode is desired, the CRU error processing would adjust to interpreting the truth table differently or utilizing a different table altogether that accounts for the two samples per baud rate inherent in APD. In APD mode, instead of relying on an error signal that compares two adjacent data points (as in MMPD), the system would ensure phase alignment by examining the consistency between the phase of the received signal and two phase points, one ahead and one behind, effectively doubling the phase information used for correction. By configuring the CRU to interpret these signals according to the mode of phase detection-whether MMPD or APD the SerDes system gains the flexibility to adjust its phase correction method to suit the operational context, maximizing data integrity and minimizing bit error rates under varying channel conditions and baud rates.

For example, some embodiments herein enable an adaptable clock recovery protocol, which may seamlessly switch between APD and MMPD. For example, based on the link's channel loss and actual data rate in each application, the same clock recovery unit may be operable to function as either APD or MMPD and retain both robustness and power efficiency. As discussed further, such adaptability eases CTLE specifications (e.g., CTLE 102).

For example, only utilizing MMPD across broad frequency range becomes challenging when the same link must operate at 10's of GHz sample rate with high loss, and at a few GHz sampling rate, where in general channel loss is low. MMPD protocol, which works with one sample per unit interval (UI), needs some finite channel loss (6-10 dB at Nyquist frequency) to achieve a robust lock point. Such lock point significantly depends on the pulse response. If the external channel loss is low, the requirement falls on to the CTLE 102, 202 which preceded the phase detector, to give the loss at Nyquist frequency. Thus CTLE 102, 202 may be specified to give a boost at the maximum Nyquist rate, and to give loss of 6 dB at minimum Nyquist rate.

In some embodiments, the ratio between the maximum and minimum baud-rate can be as high as 30 or more. The dynamic range of gain requirement at Nyquist may be high (e.g., >20 dB generally). Further, because of baud-rate variation, change in peaking frequency also needs to be supported, which makes it almost impossible to design the CTLE. Thus, by implementing the one or more of the embodiments herein, CTLE 102, 202 will not need to provide loss below maximum-baud rate by 2. Below those baud-rates, APD protocol may be implemented. As APD needs two samples per baud, CTLE may operate only below maximum clock rate by 2 in a given design implementation. In some embodiments, APD may operate with both high and low channel loss, and hence CTLE may support 20 dB gain change in 2× frequency range rather than over 30× frequency range.

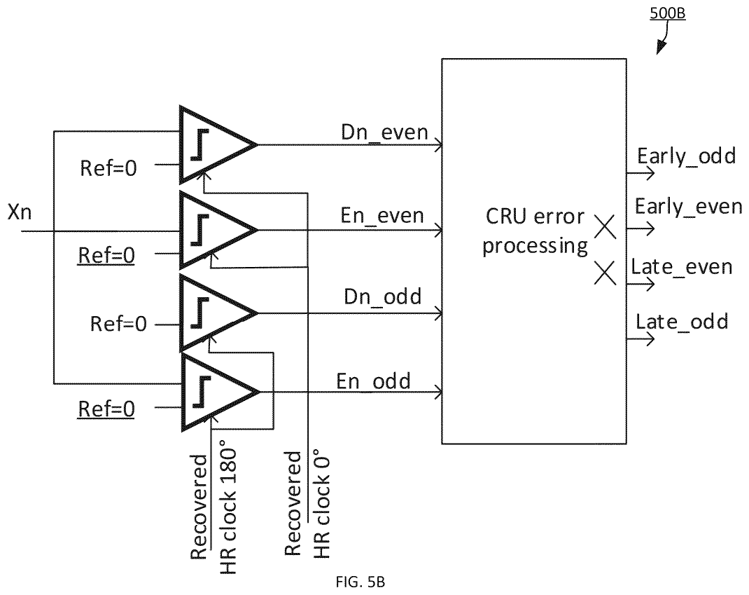

Referring now to FIG. 5A-5B, in conjunction with FIGS. 1-4, FIG. 5A depicts a SerDes architecture that incorporates Mueller-Muller Phase Detection (MMPD) with an even-odd time-interleaved architecture System 500A. FIG. 5B depicts system 500B, which is an embodiment of system 500A, wherein to implement Alexander Phase Detection (APD), system 500B the systems and methods of the embodiments herein for adapting phase detection mechanisms to suit different baud rates and channel conditions.

Some embodiments include an MMPD with Even-Odd Time-Interleaved Architecture. For example, FIG. 5A SerDes system 500A that uses MMPD within an even-odd time-interleaved architecture, which may be selected for higher baud-rate applications. Time interleaving may be advantageous for doubling the effective sampling rate of the system, allowing system 500A to support higher data rates without increasing the clock frequency of individual components. In such configuration, incoming data stream is split into two paths: even and odd. Each path is processed separately, with its own set of data (Dn_even, Dn_odd) and error (En_even, En_odd) slicers, and the reference voltages are set accordingly (Ref=0, Ref=±h0).

As shown in FIGS. 5A-5B, CRU error processing unit receives the early and late signals from both even and odd channels and adjusts the clock recovery process to ensure that the data is sampled at the optimal point. This error processing is critical for maintaining data integrity, especially at high speeds where the timing becomes increasingly sensitive to perturbations.

In some embodiments, system 500 may include an APD implementation in the Same Architecture. As shown in FIG. 5B, in some embodiments, system 500B may implement APD. APD is known for robustness, especially in conditions of low channel loss, making APD advantageous in specific scenarios where MMPD may not perform as well. In some embodiments, to switch to APD mode, the references for h0 are set to 0V, effectively changing the decision thresholds for slicers 504, 506. Additionally, CRU error processing unit 509 may be adjusted to ignore certain early and late signals—for example, from either the even or odd stream. Such selective ignoring of signals simulates the two-sample-per-baud requirement of APD. Thus, the resulting behavior of the CRU error processing 509 will mimic that of APD, offering system 500B the robustness against low channel loss while still taking advantage of the interleaved architecture. Such selective functionality allows for a single hardware design to operate in two distinct modes, providing flexibility in adapting to the requirements of the operating environment.

In some embodiments, system 500 may extend to other interleaved architectures. For example, interleaving architectures, such as 1-way or n-way interleaving. Adjusting the reference voltages and the error signal processing to switch between phase detection methods will apply as described above. Such adaptability is advantageous in systems that operate across a range of conditions, as it allows for on-the-fly adjustments to maintain optimal performance without the need for hardware changes. Such dual-mode capability ensures that the SerDes receiver of the systems and methods herein may maintain high performance and reliability, from high data rate scenarios where power efficiency is advantageous, to more challenging low-loss channels where robust phase detection ensures signal integrity.

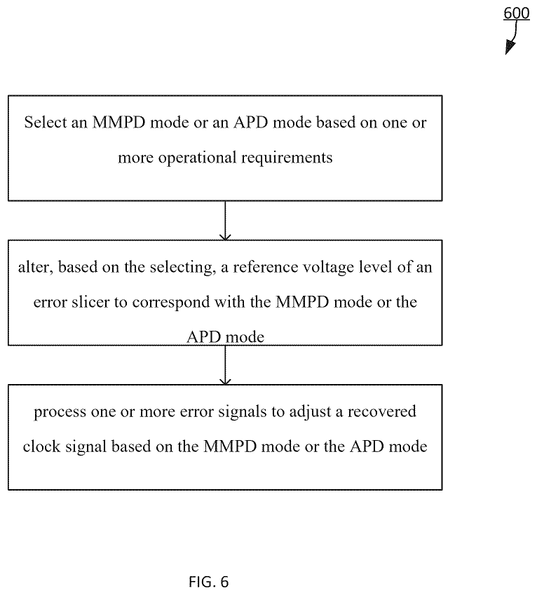

Referring now to FIG. 6, FIG. 6 depicts a flowchart is shown illustrating a method 600 for dual-mode phase detection in a SerDes receiver system, in accordance with some embodiments. As shown, method 600 begins at block 602, where an MMPD mode or an APD mode is selected based on one or more operational requirements. For example, operational requirements may include detected channel loss, baud rate, jitter margin, or desired power efficiency. At block 604, based on the selected mode, a reference voltage level of one or more error slicers is altered to correspond with the selected mode. In some embodiments, altering the reference voltage includes setting the reference to zero volts for APD mode, and to for MMPD mode. At block 606, one or more error signals are processed to adjust a recovered clock signal in accordance with the selected phase detection mode. The recovered clock signal may be adjusted via a phase interpolator or equivalent circuitry responsive to the processed error signals. Method 600 enables the system to flexibly support both power-efficient MMPD and robust APD within a common receiver architecture.

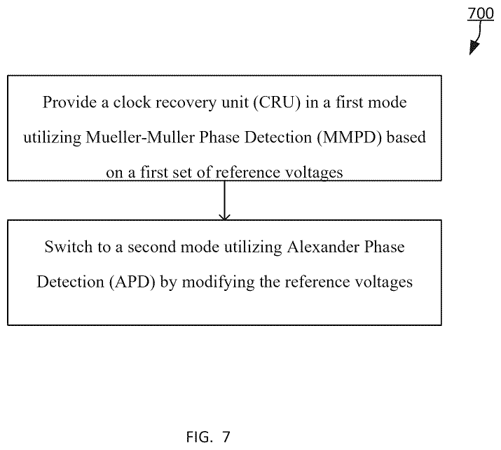

Referring now to FIG. 7, a flowchart is shown illustrating a method 700 for hybrid clock recovery operation using shared circuitry for phase detection, in accordance with some embodiments. As shown, method 700 may begin at block 702, where a clock recovery unit (CRU) is operated in a first mode corresponding to Mueller-Muller Phase Detection (MMPD), based on a first set of reference voltages. For example, MMPD operation may rely on non-zero reference voltages applied to one or more error slicers to generate phase error signals from sampled data. At block 704, the method includes switching the CRU to a second mode corresponding to Alexander Phase Detection (APD) by modifying the reference voltages.

In some embodiments, the switching includes setting one or more reference voltages to zero volts and optionally ignoring early/late signals from selected interleaved data paths. Such transition may be performed dynamically or under control of a mode selector or system controller. Method 700 thus enables the same CRU circuitry to perform both MMPD and APD without requiring separate hardware implementations for each phase detection scheme.

As SerDes technology continues to evolve, the ability to adapt to a wide variety of operating conditions while maintaining a streamlined and efficient architecture is increasingly important. Thus, as described in the recitation of the embodiments above, via the integration of digital logic and adaptive circuitry, the embodiments herein provide a solution that is both technologically advanced and practical for modern high-speed communication networks.

In some embodiments, the selection between the MMPD mode and the APD mode, as shown in FIGS. 6 and 7, may be governed by a mode selection circuit or controller operatively coupled to one or more configuration registers, programmable state machines, or external software control logic. The mode selector may determine the appropriate phase detection mode based on one or more criteria, such as: (i) measured or estimated channel loss, (ii) operating baud rate or frequency of the SerDes link, (iii) real-time signal integrity metrics such as jitter margin or bit error rate (BER), or (iv) pre-programmed system-level performance profiles (e.g., low-power vs. high-reliability modes). In some embodiments, the mode selector may operate automatically based on signal monitoring, or it may be manually invoked by a host controller or initialization routine during system bring-up.

For example, in some embodiments, the system may default to MMPD mode during high-speed operation when the measured channel loss exceeds a predefined threshold (e.g., >6 dB at the Nyquist frequency), as MMPD is generally more power-efficient. Conversely, if the measured or expected loss falls below the threshold, or if the baud rate is below a pre-determined frequency (e.g., 5 GHZ), the system may switch to APD mode to gain increased robustness against jitter and timing drift. These thresholds are non-limiting and may be programmable to accommodate a wide range of deployment scenarios.

In some embodiments, the transition between MMPD and APD modes may be performed dynamically and without interrupting the data stream, depending on implementation. For instance, the CRU may include glitchless switching logic, such as synchronizers, debounce circuits, or dual-clock domain safe MUXes, to enable live mode transitions. Alternatively, the transition may require a short re-lock or re-synchronization period where data is temporarily buffered or muted while the recovered clock phase realigns under the newly selected mode. The CRU may optionally retain phase tracking context or reuse previous loop filter values to shorten reacquisition time.

In embodiments that support real-time adaptive switching, the mode selector may continuously monitor channel conditions during operation and adjust the CRU's mode on-the-fly in response to changing system parameters. For instance, as a high-speed link enters a power-saving state or encounters reduced interference, the mode selector may proactively switch to APD mode to increase jitter margin, and revert to MMPD mode as data rate or channel conditions change. This ability to seamlessly reconfigure the phase detection method provides increased flexibility and optimization across a wide operational envelope.

To support this dual-mode functionality, the CRU may share core comparator circuitry (e.g., slicers), signal paths, and counters between MMPD and APD modes, reducing area and power overhead. As described earlier, the slicer reference voltages may be switched digitally between a non-zero valuefor MMPD operation and zero volts for APD operation. In APD mode, additional logic may be employed to selectively ignore early or late signals from one half of an interleaved data stream (e.g., ignore even paths), effectively mimicking a two-sample-per-baud architecture within an otherwise time-interleaved MMPD framework.

In some embodiments, the early/late signal processing logic may reside in a CRU error processing unit, which includes a digital finite state machine or signal processor configured to evaluate phase error conditions using different truth tables or correlation logic depending on the selected mode. This logic may be implemented in hardware, firmware, or a combination thereof. For example, in MMPD mode, the CRU may use the correlation logic of Table 1 or Table 2, whereas in APD mode, correlation equations such as Eqns. 5a-6 may be applied instead.

Furthermore, the dual-mode design reduces the equalization burden on the CTLE. As discussed previously in paragraphs [0043]-[0044], MMPD performance is highly sensitive to the pulse response of the channel, which in turn requires significant peaking and gain control in the CTLE, especially across a broad baud rate range. By enabling APD operation at lower baud rates (e.g., below half the maximum rate), the CTLE's required dynamic gain range and peaking frequency variation are significantly reduced. This allows for simpler CTLE designs that consume less power and occupy less die area, while still maintaining robust clock recovery across all supported rates.

In some embodiments, for hardware/software partitioning, one or more features discussed herein of the CRU and mode selector may be implemented in firmware or register-configured logic blocks, such as in a PHY controller or embedded microcontroller. For example, the logic that monitors operating conditions and selects the phase detection mode may be implemented in microcode or firmware routines, while the error slicer comparators, data path MUXing, and reference voltage selectors may be implemented in analog or digital hardware. This hybrid hardware/software architecture enables design flexibility, post-silicon tuning, and adaptive calibration in the field.

Finally, although the above embodiments have primarily been described in the context of even-odd time-interleaved architectures, the systems and methods disclosed herein are equally applicable to 1-way (non-interleaved) and n-way interleaved receiver designs. In such architectures, similar principles may be used to adjust which sampling phases contribute to the CRU error signal, and how the phase detection equations are implemented in the processing logic. The mode selection techniques and reference switching principles disclosed herein are extensible to various SerDes architectures, enabling scalable, efficient, and robust phase recovery solutions for high-speed communication systems.

The embodiments described herein may be embodied in systems, apparatus, methods, computer programs and/or articles depending on the desired configuration. Any methods or the logic flows depicted in the accompanying figures and/or described herein do not necessarily require the particular order shown, or sequential order, to achieve desirable results. The implementations set forth in the foregoing description do not represent all implementations consistent with the subject matter described herein. Instead, they are merely some examples consistent with aspects related to the described subject matter. Although a few variations have been described in detail above, other modifications or additions are possible. In particular, further features and/or variations can be provided in addition to those set forth herein. The implementations described above can be directed to various combinations and subcombinations of the disclosed features and/or combinations and subcombinations of further features noted above. Furthermore, above described advantages are not intended to limit the application of any issued claims to processes and structures accomplishing any or all of the advantages. Furthermore, any reference to this disclosure in general or use of the word “embodiment” in the singular is not intended to imply any limitation on the scope of the claims set forth below. Multiple embodiments may be set forth according to the limitations of the multiple claims issuing from this disclosure, and such claims accordingly define the embodiment(s) herein, and their equivalents, that are protected thereby.

In the claims, any reference signs placed between parentheses shall not be construed as limiting the claim. The word “comprising” or “including” does not exclude the presence of elements or steps other than those listed in a claim. In a device claim enumerating several means, several of these means may be embodied by one and the same item of hardware. The word “a” or “an” preceding an element does not exclude the presence of a plurality of such elements. In any device claim enumerating several means, several of these means may be embodied by one and the same item of hardware. The mere fact that certain elements are recited in mutually different dependent claims does not indicate that these elements cannot be used in combination.

Although the description provided above provides detail for the purpose of illustration based on what is currently considered to be the most practical and preferred embodiments, it is to be understood that such detail is solely for that purpose and that the disclosure is not limited to the expressly disclosed embodiments, but, on the contrary, is intended to cover modifications and equivalent arrangements that are within the spirit and scope of the appended claims. For example, it is to be understood that the present disclosure contemplates that, to the extent possible, one or more features of any embodiment can be combined with one or more features of any other embodiment.

1. A system for a serializer/deserializer (SerDes) receiver operable to implement a first mode corresponding to a Mueller-Muller Phase Detection (MMPD) operation or a second mode corresponding to an Alexander Phase Detection (APD) operation, the first mode and the second mode configured for clock recovery, the system comprising:
a data slicer;
an error slicer; and
a phase detector configured to operate in the first mode corresponding to MMPD and the second mode corresponding to APD,
wherein the phase detector is configured to adjust a phase of a recovered clock signal based on one or more error signals generated by the data slicer and/or the error slicer.

2. The system of claim 1, further including a mode selector configured to alter a reference voltage level of the data slicer or the error slicer to switch between the first mode and the second mode.

3. The system of claim 2, wherein the mode selector sets the reference voltage level to zero volts to enable operation in the second mode corresponding to APD.

4. The system of claim 1, wherein the phase detector comprises an even-odd time-interleaved architecture to accommodate a baud rate when operating in the first mode corresponding to MMPD.

5. The system of claim 1, wherein the phase detector is further configured to ignore an early and/or late signal corresponding to an even or odd data streams when operating in the second mode corresponding to APD.

6. The system of claim 1, wherein the error slicer generates early and/or late signals based on a truth table that generates phase detector outputs for advancing or delaying the recovered clock signal.

7. The system of claim 6, wherein the truth table is adapted to support both MMPD and APD functionalities by changing error signal processing parameters.

8. The system of claim 1, wherein the clock recovery system is adaptable to n-way interleaved architectures for phase detection.

9. A method for operating a clock recovery system in a SerDes receiver, the method comprising:
selecting an MMPD mode or an APD mode based on one or more operational requirements;
altering, based on the selecting, a reference voltage level of an error slicer to correspond with the MMPD mode or the APD mode; and
processing error signals to adjust a recovered clock signal in accordance with the selected mode.

10. A method for dual-mode phase detection in a serializer/deserializer (SerDes) system, the method comprising:
operating a clock recovery unit (CRU) in a first mode utilizing Mueller-Muller Phase Detection (MMPD) based on a first set of reference voltages; and
switching to a second mode utilizing Alexander Phase Detection (APD) by modifying the reference voltages.

11. The method of claim 10, further comprising selecting the first mode or the second mode based on one or more operating conditions, the operating conditions including at least one of: measured channel loss, data rate, jitter margin, or system power mode.

12. The method of claim 10, wherein switching to the second mode includes setting reference voltages to zero and selectively ignoring error signals associated with even or odd interleaved data paths.

13. The method of claim 10, further including generating error signals through data slicers and/or error slicers driven by a recovered clock, wherein the error signals correspond to the timing discrepancies between the incoming data and the recovered clock.

14. The method of claim 10, wherein the first mode of operation involves even-odd time interleaving to increase the effective sampling rate without increasing a clock frequency.

15. The method of claim 10, wherein the second mode of operation employs double sampling per baud rate, based on APD, configured to enhance phase detection robustness in low channel loss environments.

16. The method of claim 10, further including adapting the phase detection process to support a 1-way and n-way interleaved architecture.

17. The method of claim 10, further including utilizing a truth table for determining whether the CRU should advance or delay a phase of the recovered clock based on the first mode or the second mode of phase detection.

18. The method of claim 10, wherein the first mode and/or the second mode is/are selectable based on one or more of: channel conditions, baud rate requirements, and/or power efficiency considerations.

19. The method of claim 10, further including configuring the CRU to process phase error signals according to the selected mode of operation, where processing for MMPD differs from processing for APD.

20. The method of claim 10, further comprising dynamically adjusting the CRU operation to transition between MMPD and APD modes on-the-fly, allowing for real-time adaptation to changes in data transmission conditions.
